(19) United States
(12) Patent Application Publication
(10) Pub. No.: US 2023/0077761 A1
(43) Pub. Date: Mar. 16, 2023

(54) LIGHT-EMITTING DEVICE AND DISPLAY DEVICE

(71) Applicant: Quanzhou Sanan Semiconductor Technology Co., Ltd., Quanzhou (CN)

(72) Inventors: Chung-Ying CHANG, Xiamen (CN); Yi-Jui HUANG, Xiamen (CN); Tsung-Ming LIN, Xiamen (CN); Kunta HSIEH, Quanzhou (CN); Ji-Pu WU, Xiamen (CN); Yu-Tsai TENG, Xiamen (CN)

(21) Appl. No.: 17/931,344

(22) Filed: Sep. 12, 2022

(30) Foreign Application Priority Data
Sep. 14, 2021 (CN) 202111076835.1

(51) Int. Cl. H01L 33/42; H01L 33/14; H01L 33/20

(52) U.S. Cl. CPC H01L 33/42; H01L 33/145; H01L 33/20

(57) ABSTRACT

A light-emitting device includes a substrate, a semiconductor structure, and an insulating reflective layer. The substrate has an upper surface and a lower surface. The semiconductor structure is disposed on the upper surface of the substrate. A projection of the semiconductor structure on the upper surface of the substrate has an outer periphery spaced apart a distance from an outer periphery of the upper surface of the substrate. The insulating reflective layer covers at least a part of the semiconductor structure and has an extending portion extending outwardly from the semiconductor structure and covering a part of the upper surface of the substrate. A peripheral end of the extending portion of the insulating reflective layer has an inclined lateral surface, and an included angle defined between the inclined lateral surface and the upper surface of the substrate is not less than 60°.

### CROSS-REFERENCE TO RELATED APPLICATION

This application claims priority of Chinese Invention Patent Application No. 202111076835.1, filed on Sep. 14, 2021.

### FIELD

The disclosure relates to a light-emitting device and a display device.

### BACKGROUND

Light-emitting diodes (LEDs) are solid-state semiconductor light-emitting devices which include different types of light-emitting materials and light-emitting components. LEDs, having advantages such as low cost, low power consumption, high luminous efficiency, small size, energy saving, and good photoelectric properties, are widely used in various applications such as lighting devices, visible light communication devices, and display devices.

### SUMMARY

An object of the disclosure is to provide a light-emitting device with high reliability.

According to a first aspect of the disclosure, a light-emitting device include a substrate, a semiconductor structure, and an insulating reflective layer. The substrate has an upper surface and a lower surface opposite to the upper surface. The semiconductor structure is disposed on the upper surface of the substrate, and includes a first semiconductor layer, a second semiconductor layer, and a light-emitting layer disposed between the first semiconductor layer and the second semiconductor layer. A projection of the semiconductor structure on the upper surface of the substrate has an outer periphery spaced apart a distance (D2) from an outer periphery of the upper surface of the substrate. The insulating reflective layer covers at least a part of the semiconductor structure and has an extending portion extending outwardly from the semiconductor structure and covering a part of the upper surface of the substrate. A peripheral end of the extending portion of the insulating reflective layer has an inclined lateral surface, and an included angle defined between the inclined lateral surface and the upper surface of the substrate is not less than 60°.

According to a second aspect of the disclosure, a display device includes a mounting element and the aforesaid light-emitting device that is mounted on the mounting element.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic top view illustrating a first embodiment of a light-emitting device according to the disclosure.

FIG. 2 is a schematic top view illustrating the first embodiment of the light-emitting device, in which a first electrode pad, a second electrode pad, and an insulating reflective layer are omitted.

FIG. 3 is a cross-sectional view taken along line X-X′ of FIG. 1.

FIG. 4 is a partially enlarged view of area A in FIG. 3.

FIG. 5 is a partially enlarged view of area A in FIG. 3, illustrating an insulating reflective layer of the first embodiment.

FIG. 6 shows inspection light paths of a light-emitting device of a comparative example.

FIG. 7 shows inspection light paths of the light-emitting device of the first embodiment according to the disclosure.

FIG. 8 is a partially enlarged view of area C in FIG. 3.

FIG. 9 is a partially enlarged view of area B in FIG. 3.

FIG. 10 is a schematic top view illustrating a second embodiment of the light-emitting device according to the disclosure.

FIG. 11 is a schematic top view illustrating the second embodiment of the light-emitting device, in which a first electrode pad, a second electrode pad, and an insulating reflective layer are omitted.

FIG. 12 is a cross-sectional view taken along line X-X′ of FIG. 10.

FIG. 13 is a schematic top view illustrating a third embodiment of the light-emitting device according to the disclosure.

FIG. 14 is a schematic top view illustrating the third embodiment of the light-emitting device, in which a first electrode pad, a second electrode pad, and an insulating reflective layer are omitted.

FIG. 15 is a cross-sectional view taken along line X-X′ of FIG. 13.

FIG. 16 is a sectional view illustrating a fourth embodiment of the light-emitting device according to the disclosure.

FIG. 17 is a partially enlarged view of area E in FIG. 16.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

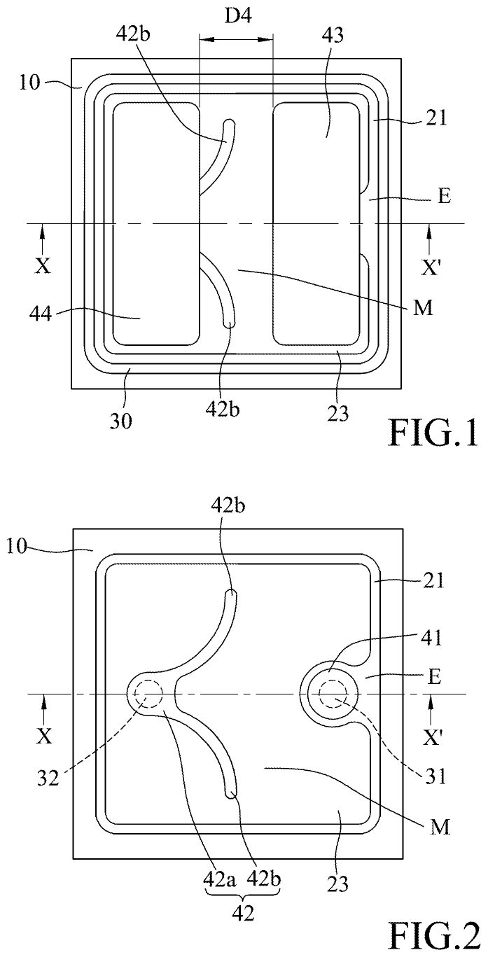

Referring to FIGS. 1 to 3, a light-emitting device according to a first embodiment of the disclosure includes a substrate 10, a semiconductor structure 20, a first contact electrode 41, a second contact electrode 42, an insulating reflective layer 30, a first electrode pad 43, and a second electrode pad 44.

The light-emitting device may be a common size LED, which have a horizontal cross-sectional area ranging from about 90000 μm² to about 2000000 μm².

The light-emitting device may be a small size or a mini LED, which have a horizontal cross-sectional area less than 90000 μm². For example, the light-emitting device may have a length and a width at least one of which ranges 100 μm to 300 μm, and a thickness which ranges 40 μm to 150 μm.

The light-emitting device may be a micro LED, which have a horizontal cross-sectional area less than 10000 μm². For example, the light-emitting device may have a length ranging from 2 μm to 100 μm, a width ranging from 2 μm to 100 μm, and a thickness ranging from 2 μm to 100 μm. However, the length, width and thickness of the light-emitting device of the disclosure are not limited to such ranges.

The substrate 10 has an upper surface 11 and a lower surface 12 opposite to the upper surface 11. The semiconductor structure 20 is disposed on the upper surface 11 of the substrate 10. The substrate 10 may be a light-transmissive substrate, an opaque substrate, or a translucent substrate. When the substrate 10 is a light-transmissive substrate or a translucent substrate, light emitted from the semiconductor structure 20 may pass through the substrate 10 in a direction away from the semiconductor structure 20. In certain embodiments, the substrate 10 may be a growth substrate provided for growth of the semiconductor structure 20. As a growth substrate, the substrate 10 may be a sapphire substrate, a silicon nitride (SiN) substrate, a silicon substrate, a gallium nitride (GaN) substrate, or an aluminum nitride (AlN) substrate. In certain embodiments, the substrate 10 may have a thickness less than the short side length of the light-emitting device. In certain embodiments, the substrate 10 may have a thickness less than 200 μm, e.g., 150 μm, 100 μm, or 80 μm.

In this embodiment, at least a portion of the upper surface 11 of the substrate 10 is formed with an uneven structure 13 for improving the external light extraction efficiency and the crystallinity of a semiconductor material that forms the semiconductor structure 20. In this embodiment, the uneven structure 13 has structured elements which are dome-shaped protrusions. In other embodiments, the structured elements of the uneven structure 13 are protrusions, that may have at least one of a trapezoid-shape, a circular cone-shape, a triangular cone-shape, a hexagonal cone-shape, a circle-like cone-shape, a triangle-like cone-shape, and a hexagon-like cone-shape. The uneven structure 13 may be formed by embossing, dry etching, or wet etching. The uneven structure 13 may be formed at any selected areas on the substrate 10, or may be omitted. For example, the lower surface 12 of the substrate 10 may be formed with the uneven structure 13 for improving the external light extraction efficiency of the semiconductor material that forms the semiconductor structure 20. In some embodiments, the uneven structure 13 has structured elements or protrusions that are distributed on the upper surface 11 of the substrate 10. The uneven structure 13 and the substrate 10 may be made of a same material or different materials. If the uneven structure 13 and the substrate 10 are made of different materials, the material of the uneven structure 13 may have a refractive index that is lower than that of the material of the substrate 10, so as to improve the external light extraction efficiency of the light-emitting device. In some embodiments, the uneven structure 13 is made of SiO₂ and has protrusions of substantially circular cone-shape. In other embodiments, the uneven structure 13 include at least one layer having a refractive index lower than that of the substrate 10. For example, the uneven structure 13 may be configured to have double layers; the bottom layer thereof may be made of a material the same as that of the substrate 10, while the top layer thereof is made of a material having a refractive index lower than that of the material of the substrate 10. In such configuration, the top layer may have a thickness more than twice that of the bottom layer.

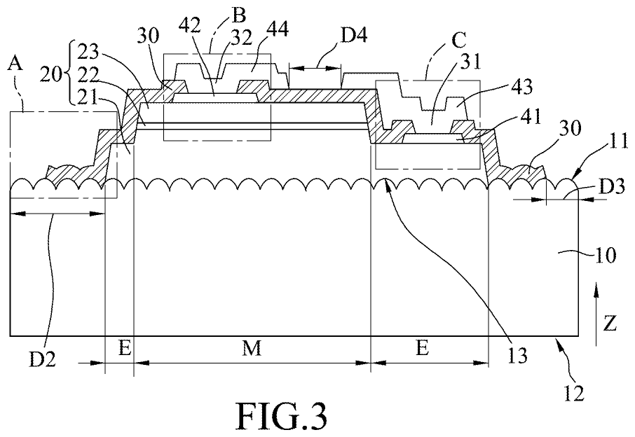

The semiconductor structure 20 may have a lower surface with an area that is smaller than an area of the upper surface 11 of the substrate 10, such that a portion of the upper surface 11 of the substrate 10 located around the semiconductor structure 20 is exposed. When the semiconductor structure 20 is subjected to a multi-focus cutting process, if a focus is too close to the semiconductor structure 20, the semiconductor structure 20 may be damaged. In order to avoid such situation, as shown in FIG. 3, a projection of the semiconductor structure 20 on the upper surface 11 of the substrate 10 has an outer periphery spaced apart a distance (D2) from an outer periphery of the upper surface 11 of the substrate 10, and the distance (D2) is greater than 0. To be more specific, the distance (D2) may range from 5 μm to 30 μm, such as from 10 μm to 30 μm, e.g., from 15 μm to 25 μm. The uneven structure 13 may have a part that is located under the semiconductor structure 20, and another part that is located around the semiconductor structure 20.

In this embodiment, since the portion of the upper surface 11 of the substrate 10 that is located around the semiconductor structure 20 is exposed, a warpage of the light-emitting device can be reduced during the manufacturing process thereof, thereby preventing the semiconductor structure 20 from being damaged, and improving the manufacturing yield of light-emitting devices. In addition, as the risk of warpage of the light-emitting device may be reduced, stress imposed on the semiconductor structure 20 may also be reduced, so that the substrate 10 can be made thinner. In this embodiment, the substrate 10 is a sapphire substrate having the upper surface 11 which is formed with the uneven structure 13. However, in other embodiments, the substrate 10 can be omitted.

The semiconductor structure 20 is disposed on the upper surface 11 of the substrate 10, and includes a first semiconductor layer 21, a second semiconductor layer 23, and a light-emitting layer 22 disposed between the first semiconductor layer 21 and the second semiconductor layer 23.

In this embodiment, the first semiconductor layer 21, the light-emitting layer 22, and the second semiconductor layer 23 are epitaxially formed on the substrate 10. In other embodiments, the semiconductor structure 20 may be attached to the substrate 10 by an adhesive layer (not shown). The adhesive layer may be a light-transmissive material or a translucent material, such as silicon dioxide, aluminum oxide, etc.

The first semiconductor layer 21 of the semiconductor structure 20 is disposed on the upper surface 11 of the substrate 10. In some embodiments, the first semiconductor layer 21 is an N-type doped layer. For example, the first semiconductor layer 21 may be made of a Group II-VI semiconductor material such as zinc selenide (ZnSe), or a Group III-V nitride material such as gallium nitride (GaN), aluminum nitride (AlN), indium nitride (InN), indium gallium nitride (InGaN), aluminum gallium nitride (AlGaN), and aluminum indium gallium nitride (AlInGaN). The first semiconductor layer 21 may include dopants such as silicon (Si) or germanium (Ge). In certain embodiments, the first semiconductor layer 21 may have a single-layer or multilayered structure.

The light-emitting layer 22 is disposed on the first semiconductor layer 21. The light-emitting layer 22 can emit light of different wavelengths depending on its material. For example, the light-emitting layer 22 made of InGaN materials can emit blue light (including dark blue light) with a wavelength between 400 nm and 490 nm, or green light with a wavelength between 490 nm and 550 nm. The light-emitting layer 22 made of AlGaN materials can emit UV light with a wavelength between 220 nm and 400 nm. In some embodiments, the light-emitting layer 22 may include at least one undoped semiconductor layer or at least one low-doped layer. For example, the light-emitting layer 22 may be a single quantum well layer, which may increase the electron-hole collision rate so as to enhance the electron-hole binding rate and luminescence efficiency, and which may include InGaN or GaN. In certain embodiments, the light-emitting layer 22 may be a multi-layer quantum well structure.

The second semiconductor layer 23 is disposed on the light-emitting layer 22. In some embodiments, the second semiconductor layer 23 is a P-type doped layer. For example, the second semiconductor layer 23 may be made of a Group III-V nitride material such as gallium nitride (GaN), aluminum nitride (AlN), indium nitride (InN), indium gallium nitride (InGaN), aluminum gallium nitride (AlGaN), or aluminum indium gallium nitride (AlInGaN). The second semiconductor layer 23 may include dopants such as magnesium (Mg) or carbon (C). In certain embodiments, the second semiconductor layer 23 may have a single-layer or multilayered structure.

Referring to FIGS. 2 and 3, in this embodiment, the semiconductor structure 20 includes a mesa portion (M) and a recessed portion (E). The recessed portion (E) is formed by penetrating the light-emitting layer 22 and the second semiconductor layer 23 to expose a portion of the first semiconductor layer 21. At the recessed portion (E), the second semiconductor layer 23, the light-emitting layer 22, and a portion of the first semiconductor layer 21 had been removed. The mesa portion (M) is surrounded by the recessed portion (E). The mesa portion (M) can be defined as a portion of the semiconductor structure 20 where the second semiconductor layer 23, the light-emitting layer 22, and the first semiconductor layer 21 are not etched. The mesa portion (M) protrudes relative to the recessed portion (E) in a vertical direction (indicated by the arrow Z in FIG. 3). The recessed portion (E) can also be defined as an etched portion. In some embodiments, the mesa portion (M) may be defined as a portion of the semiconductor structure 20 where the second semiconductor layer 23 and the light-emitting layer 22 are not etched, and the first semiconductor layer 21 at the recessed portion (E) may be completely retained. The mesa portion (M) may be formed to taper in the vertical direction so as to have an inclined lateral surface.

The first contact electrode 41 is disposed on and electrically connected to the first semiconductor layer 21 of the semiconductor structure 20. The second contact electrode 42 is disposed on and electrically connected to the second semiconductor layer 23. Referring to FIG. 2, the second contact electrode 42 may include a main part 42a and at least one extending part 42b each extending from the main part 42a. The extending part 42b of the second contact electrode 42 can conduct current so as to facilitate current dispersion, thereby improving the luminous efficiency of the light-emitting device. Further referring to FIG. 3, the first contact electrode 41 may be located on the recessed portion (E) of the semiconductor structure 20, and the second contact electrode 42 may be located on the mesa portion (M) of the semiconductor structure 20. In a top view, the main part 42a of the second contact electrode 42 may have a circular shape, a horseshoe shape, or an oval shape, and the extending part 42b of the second contact electrode 42 may have a strip-like shape, a rectangular shape, or a polygonal shape. In certain embodiments, the main part 42a of the second contact electrode 42 has an upper surface having a width ranging from 15 μm to 50 μm. The main part 42a and the extending part 42b of the second contact electrode 42 may have the same multilayered structure and thickness. The first contact electrode 41 may have an extending part. In this embodiment, however, the first contact electrode 41 does not have any extending part so as to ensure a larger light-emitting area of the light-emitting device. The first contact electrode 41 may have a circular shape, a horseshoe shape, or an oval shape in a top view.

In some embodiments, the light-emitting device may include a plurality of the first contact electrodes 41 and a plurality of the second contact electrodes 42.

In some embodiments, the second contact electrode 42 may at least include a main part 42a and two extending parts 42b each of that has an arc-shape and extends gradually outward with the distance from the main part 42a. The angle between the tangent line of the extending part 42b and the line X-X′ (see FIG. 2) is gradually increased in the extension direction of the extending part 42b, thereby further improving saturation current stability of the light-emitting device.

The first and second contact electrodes 41, 42 may be made of the same material and may be formed simultaneously in the same manufacturing process. For example, the first and second contact electrodes 41, 42 may be metallic electrodes including nickel, gold, chromium, titanium, platinum, palladium, rhodium, iridium, aluminum, tin, indium, tantalum, copper, cobalt, iron, ruthenium, zirconium, tungsten, molybdenum or a combination thereof, and thus may have the same stacked structure. Further, the first and second contact electrodes 41, 42 may include an Al reflection layer and an Au connection layer. In some embodiments, the first and second contact electrodes 41, 42 may have a stacked structure including Cr/Al/Ti/Ni/Ti/Ni/Au/Ti layers. In other embodiments, the first and second contact electrodes 41, 42 may have a stacked structure including Cr/Al/Ti/Al/Ti/Al/Ti/Pt layers, in which the lower one of the Al layer is mainly used as a reflection layer, the upper one of the Al layer is mainly used as a lateral current expansion layer, and the Pt layer (i.e., the top layer) is used as an etch stop layer. Preferably, the Pt layer have a thickness greater than 100 nm, e.g., ranging from 130 nm to 400 nm. The Pt layer having appropriate thickness may increase the lateral current expansion capability of the electrodes, and may facilitate hole etching processes of the insulating reflective layer 30. In certain embodiments, the light-emitting device is a mini LED, for example, having a size of 4 mil*8 mil. Each of the first and second contact electrodes 41, 42 may have a stacked structure that includes Cr/Al/Ti/Pt layers so as to be capable of reducing the thickness thereof to less than 500 nm. Such configuration may improve coverage continuities of the insulating reflective layer 30 and electrode pads (i.e., first and second electrode pads 43, 44) above the first and second contact electrodes 41, 42, and thereby improving the reliability of the light-emitting device.

The insulating reflective layer 30 covers at least a part of the semiconductor structure 20 and has an extending portion extending outwardly from the semiconductor structure 20 and covering a part of the upper surface 11 of the substrate 10. Specifically, in this embodiment, the insulating reflective layer 30 covers an upper surface and a lateral surface of the semiconductor structure 20, and covers the first and second contact electrodes 41, 42. Since the insulating reflective layer 30 has the extending portion that is in contact with the upper surface 11 of the substrate 10, the insulating reflective layer 30 can more stably cover the lateral surface of the semiconductor structure 20. In some embodiments, the insulating reflective layer 30 has a thickness greater than 1 μm, such as ranging from 1 μm to 10 μm, from 1 μm to 6 μm, or from 2 μm and 6 μm. The insulating reflective layer 30 may have a risk of chipping if the thickness thereof is too large.

Referring to FIG. 5, in some embodiments, the insulating reflective layer 30 includes a distributed Bragg reflector (DBR) 33. The DBR 33 may include an interface layer 33a having a relatively thick thickness, and a stacked structure 33b that is disposed on the interface layer 33a and that includes a plurality of dielectric layers having different refractive indices. The interface layer 33a, serving as a lowermost layer of the DBR 33, can improve the film quality of the DBR 33.

For example, the interface layer 33a of the DBR 33 may be made of SiO₂ and may have a thickness ranging from 50 nm to 200 nm. The stacked structure 33b of the DBR 33 may include TiO₂ layers and SiO₂ layers that are alternately stacked on one another on the interface layer 33a.

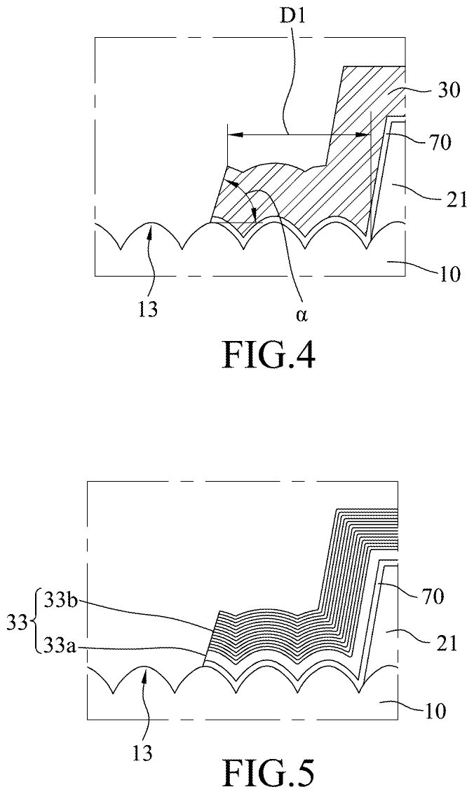

In this embodiment, the insulating reflective layer 30 may cover a part of an exposed portion of the upper surface 11 of the substrate 10. To be specific, as shown in FIG. 3, the insulating reflective layer 30 may cover an exposed portion of the upper surface 11 that is exposed from the semiconductor structure 20 and that is formed with the uneven structure 13. In other word, the insulating reflective layer 30 may cover a part of the uneven structure 13. The surface of the insulating reflective layer 30 that covers the exposed portion of the upper surface 11 may have a surface profile substantially similar to that of the portion of the upper surface 11, i.e., may be formed with an uneven structure similar to the uneven structure 13. The insulating reflective layer 30, covering the exposed portion of the upper surface 11 of the substrate 10 where the uneven structure 13 is formed, can reflect scattered light that is scattered by the uneven structure 13, thereby improving the luminous efficiency of the light-emitting device. Referring to FIG. 4, in some embodiments, a distance (D1) between the outer periphery of the projection of the semiconductor structure 20 on the upper surface 11 of the substrate 10 and an outer periphery of a projection of an upper surface of the extending portion of the insulating reflective layer 30 on the upper surface 11 of the substrate 10 ranges from 2 μm to 10 μm, thereby improving the reliability of the light-emitting device.

In this embodiment, the DBR 33 of the insulating reflective layer 30 covers almost the whole of the upper and lateral surfaces of the semiconductor structure 20 and is capable of reflecting light, thereby increasing the luminous efficiency of the light-emitting device. Further, the insulating reflective layer 30 has the extending portion extending outwardly from the semiconductor structure 20 to cover a part of the upper surface 11 of the substrate 10 while leaving a part of an outer periphery of the upper surface 11 of the substrate 10 exposed, i.e., the outer periphery of the upper surface 11 of the substrate 10 is not covered with the insulating reflective layer 30. Thus, during a wafer dicing process (e.g., internal machining, scribing, or breaking) for forming the light-emitting devices, possible damage (e.g., peeling, cracking, etc.) to the insulating reflective layer 30 that may be caused by a laser irradiation, etc., can be prevented. In particular, in the case where the insulating reflective layer 30 includes the DBR 33, if the insulating reflective layer 30 is damaged, not only the light reflectivity of the insulating reflective layer 30 may be reduced, but also a current leakage that causes a malfunction of the light-emitting device may occur. However, according to the present embodiment, such possible problems of the light-emitting device can be prevented. In some embodiments, a distance (D3) between an outer periphery of the insulating reflective layer 30 and the outer periphery of the upper surface 11 of the substrate 10 is greater than 2 μm. In certain embodiments, the distance (D3) between the outer periphery of the insulating reflective layer 30 and the outer periphery of the upper surface 11 of the substrate 10 ranges from 2 μm to 15 μm. When the distance (D3) is too small, the insulating reflective layer 30 may be damaged during the wafer dicing process, and when the distance (D3) is too large, the reflective area of the insulating reflective layer 30 may be significantly reduced and the luminous efficiency of the light-emitting device may be reduced.

Referring to FIG. 4, a peripheral end of the extending portion of the insulating reflective layer 30 has an inclined lateral surface, and an included angle (a) defined between the inclined lateral surface of the insulating reflective layer 30 and the upper surface 11 of the substrate 10 is not less than 60°, e.g., 60°<α<90°. Such configuration may enhance the structure of the light-emitting device so that, when the light-emitting device is subjected to an automated optical inspection (AOI), an axial light or a ring light used in AOI can effectively form an image on an image sensor, so as to allow detection of undesirable cracks that may affect the reliability of the light-emitting device. In some embodiments, the included angle (α) defined between the inclined lateral surface of the extending portion of the insulating reflective layer 30 and the upper surface 11 of the substrate 10 is greater than 70°, e.g., 70°<α<90°, or 75°<α<90°.

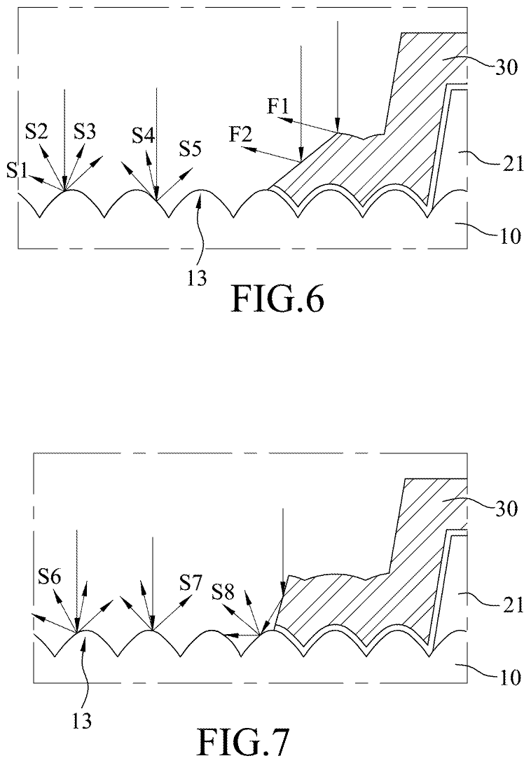

FIG. 6 shows inspection light paths on a light-emitting device of a comparative example. The comparative example of the light-emitting device has a configuration similar to that of the first embodiment of the light-emitting device, but differ in that, in the comparative example, the extending portion of the insulating reflective layer 30 has an inclined lateral surface with a smaller included angle of less than 60° (such as less than 45°). During an automated optical inspection (AOI) process, a larger amount of inspection light rays are incident on the inclined lateral surface of the extending portion of the insulating reflective layer 30 and are formed into reflected light F1, F2, whereas inspection light rays incident on the uneven structures 13 of the substrate 10 are scattered as scattered light S1, S2, S3, S4, and S5. Scattered light S1, S2, S3, S4, and S5 thus generated may increase a gray scale contrast, while the reflected light F1, F2 can hardly generate a significant gray scale contrast and thus causes failure of AOI.

Referring to FIG. 7, according to the light-emitting device of the present embodiment, because the included angle (α) defined between the inclined lateral surface of the extending portion of the insulating reflective layer 30 and the upper surface 11 of the substrate 10 is greater than 60°, the reflective area of the inclined lateral surface of the insulating reflective layer 30 is significantly reduced while scattered light S6, S7, and S8 shown in FIG. 7 are increased so that defects can be more easily detected by AOI.

Referring to FIGS. 4 and 5, in this embodiment, the light-emitting device further includes an atomic layer deposition layer 70 that is interposed between the semiconductor structure 20 and the insulating reflective layer 30. The atomic layer deposition layer 70 may be made by deposition of an oxide or nitride of aluminum (Al), hafnium (Hf), titanium (Ti), zirconium (Zr), or silicon (Si), and may has a thickness ranging from 20 nm to 200 nm. It should be noted that the atomic layer deposition layer 70 is not shown in FIG. 3 due to the small thickness thereof. Since the atomic layer deposition layer 70 has a better coatability for the surfaces of the semiconductor structure 20, it can better insulate the surfaces of the semiconductor structure 20, thus enhancing the reliability of the light-emitting device.

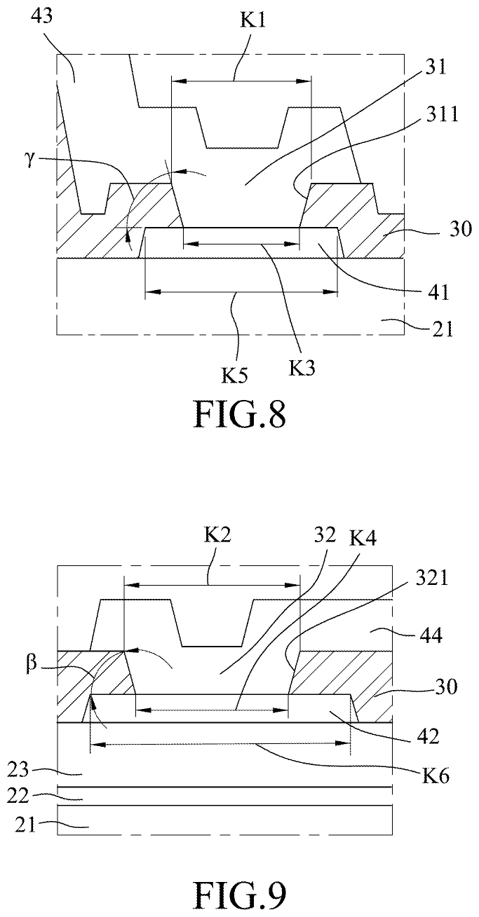

In this embodiment, the insulating reflective layer 30 further has a first through hole 31 that exposes the first contact electrode 41, a second through hole 32 that exposes the second contact electrode 42, a first hole-defining wall 311 that defines the first through hole 31, and a second hole-defining wall 321 that defines the second through hole 32. The first electrode pad 43 is disposed on the insulating reflective layer 30, and extends into the first through hole 31 to be electrically connected to the first contact electrode 41. The second electrode pad 44 is disposed on the insulating reflective layer 30, and extends into the second through hole 32 to be electrically connected to the second contact electrode 42. Referring to FIG. 2, in this embodiment, each of the first and second through holes 31, 32 is a round hole. In other embodiments, each of the first and second through holes 31, 32 may be a square hole. The particular shape and the number of the first and second through holes are not limited in the disclosure. The number of the first or second through hole 31, 32 may be one or multiple. When the number of the first or second through holes 31, 32 is multiple, electric current can be spread more evenly. In addition, when the number of the first or second through holes 31, 32 are multiple, they may be equally spaced or non-equally spaced according to the actual needs. Referring to FIGS. 8 and 9, in some embodiments, the first through hole 31 of the insulating reflective layer 30 has a top opening with a width (K1) greater than 10 μm, and a bottom opening with a width (K3) ranging from 5 μm to 40 μm; the second through hole 32 of the insulating reflective layer 30 has a top opening with a width (K2) greater than 10 μm, and a bottom opening with a width (K4) ranging from 5 μm to 40 μm.

Referring to FIG. 8, in some embodiments, a projection of the bottom opening of the first through hole 32 on an upper surface of the first contact electrode 41 falls within the upper surface of the first contact electrode 41, and the upper surface of the first contact electrode 41 has a width (K5) at least 5 μm greater than a width (K3) of the bottom opening of the first through hole 31, i.e., (K5)-(K3)≥5.

The first hole-defining wall 311 of the insulating reflective layer 30, which defines the first through hole 31, may incline relative to a bottom surface of the insulating reflective layer 30 by an included angle (γ) within 70°, e.g., ranging from 10° to 60°.

Referring to FIG. 9, in some embodiments, a projection of the bottom opening of the second through hole 32 on the upper surface of the main part 42a of the second contact electrode 42 falls within the upper surface of the main part 42a of the second contact electrode 42, and the upper surface of the main part 42a of the second contact electrode 42 has a width (K6) at least 5 μm greater than a width (K4) of the bottom opening of the second through hole 32, i.e., (K6)-(K4)≥5.

The second hole-defining wall 321, which defines the second through hole 32, may incline relative to the bottom surface of the insulating reflective layer 30 by an included angle (β) within 70°, e.g., ranging from 10° to 60°.

In some embodiments, the light-emitting device is a mini LED that may has a horizontal cross-sectional area not greater than 62500 μm². In some embodiments, in a top view, the sum of the areas of upper surfaces of the first and second electrode pads 43, 44 may occupy more than 50% of the horizontal cross-sectional area of the light-emitting device.

The upper surfaces of the first and second electrode pads 43, 44 may have the same or different shapes. As shown in FIG. 1, the shape of the upper surface of each of the first and second electrode pads 43, 44 may be a rectangle with rounded corners. Besides, at least one of the first and second electrode pads 43, 44 may be formed into a comb-shape. The shapes of the first and second electrode pads 43, 44 should not be limited to the disclosed embodiments.

The first and second electrode pads 43, 44 may be the same or different in size, which may be width or area. The first and second electrode pads 43, 44 may be made of metallic materials such as chromium (Cr), titanium (Ti), tungsten (W), aluminum (Al), indium (In), tin (Sn), nickel (Ni), platinum (Pt), or alloys of these metallic materials, and may have a single-layer or multilayered structure.

Referring back to FIG. 1, the first and second electrode pads 43, 44 are separated by a distance (D4) for maintaining an electrical isolation therebetween. In some embodiments, the distance (D4) between the first and second electrode pads 43, 44 ranges from 50 μm to 100 μm, such as from 60 μm to 80 μm. Such configuration is advantageous to ensure the reliability of the light-emitting device and to improve the heat dissipation efficiency of the light-emitting device.

In some embodiments, a distance between an outer periphery of a projection of the upper surface of the first electrode pad 43 on the upper surface 11 of the substrate 10 and an outer periphery of a projection of the upper surface of the first contact electrode 41 on the upper surface 11 of the substrate 10 is greater than 2 μm, such that the first electrode pad 43 covers the first contact electrode 41.

In some embodiments, a distance between an outer periphery of a projection of the upper surface of the second electrode pad 44 on the upper surface 11 of the substrate 10 and an outer periphery of a projection of the upper surface of the main part 42a of the second contact electrode 42 on the upper surface 11 of the substrate 10 is greater than 2 μm, such that the second electrode pad 44 covers the second contact electrode 42.

In some embodiments, a buffer layer (not shown) may be formed on the upper surface 11 of the substrate 10 prior to the formation of the first semiconductor layer 21 in order to relax the lattice mismatch between the substrate 10 and the semiconductor structure 20. The buffer layer may consist of a nitride material such as gallium nitride (GaN), aluminum gallium nitride (AlGaN), and aluminum nitride (AlN), and may have a single-layer or multilayered structure.

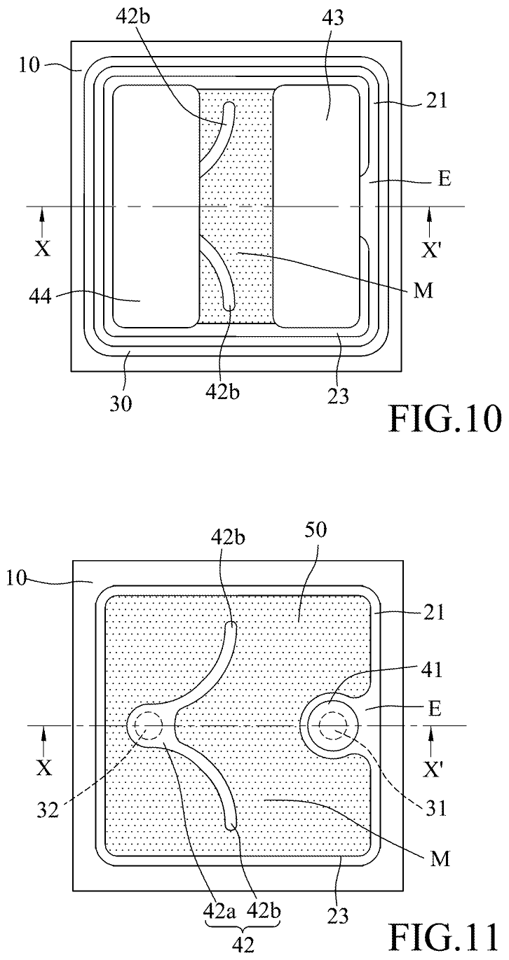

Referring to FIGS. 10 to 12, a second embodiment of the light-emitting device according to the disclosure is generally similar to the first embodiment, except that, in the second embodiment, the light-emitting device further includes a transparent conductive layer 50.

The transparent conductive layer 50 may be disposed on an upper surface of the second semiconductor layer 23 of the semiconductor structure 20. In certain embodiments, the transparent conductive layer 50 is formed on the second semiconductor layer 23 to cover most of the upper surface (e.g., at least 80% of the upper surface) of the second semiconductor layer 23. The transparent conductive layer 50 is made of a conductive light-transmitting material, and is capable of spreading the current injected from the second contact electrode 42 to prevent the current from crowding in an area of the second semiconductor layer 23. The transparent conductive layer 50 may cover the entire area of the upper surface of the second semiconductor layer 23, or cover a part of the upper surface (e.g., at least 70% of the upper surface) of the second semiconductor layer 23. For example the transparent conductive layer 50 may be made of a transparent conductive oxide such as indium tin oxide (ITO), zinc doped indium tin oxide (ZITO), zinc indium oxide (ZIO), gallium indium oxide (GIO), zinc tin oxide (ZTO), fluorine doped tin oxide (FTO), aluminum doped zinc oxide (AZO), gallium doped zinc oxide (GZO), In₄Sn₃O₁₂, and zinc magnesium oxide (Zn₍₁₋ₓ₎MgₓO, 0≤x≤1).

The thickness of the transparent conductive layer 50 is not limited, but may be in the range of about 50 Å to 3000 Å, such as 50 Å to 1500 Å. If the transparent conductive layer 50 is too thick, the transparent conductive layer 50 may absorb light passing therethrough thereby resulting in light loss; therefore, the thickness of the transparent conductive layer 50 may be limited to not greater than 3000 Å.

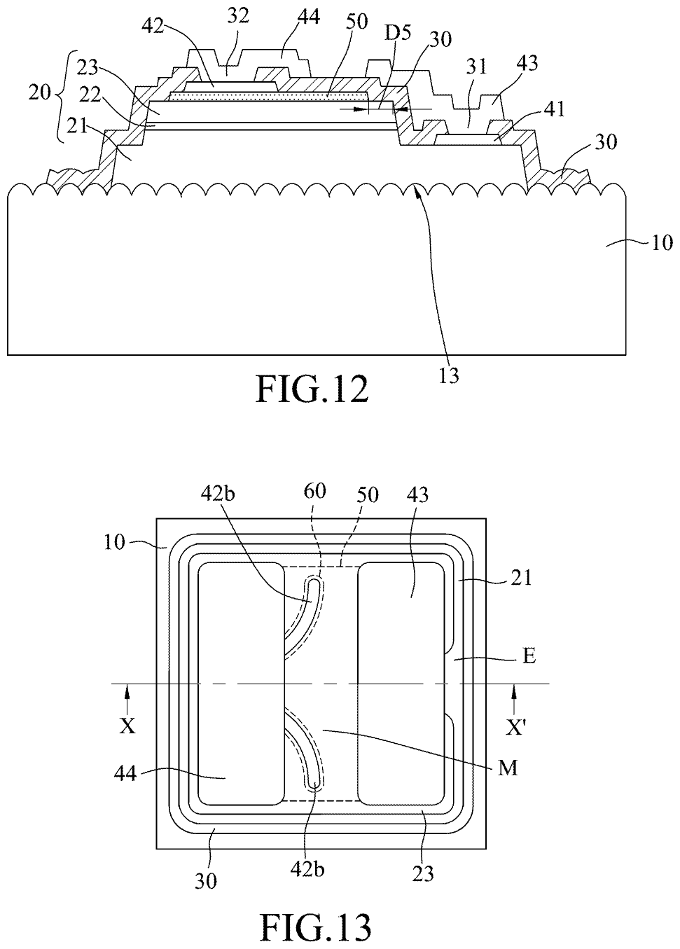

Referring to FIG. 12, in this embodiment, the transparent conductive layer 50 is disposed between the semiconductor structure 20 and the insulating reflective layer 30, and the second contact electrode 42 is disposed on and electrically connected to the transparent conductive layer 50. A projection of the transparent conductive layer 50 on the upper surface of the second semiconductor layer 23 of the semiconductor structure 20 has an outer periphery spaced apart a distance (D5) from an edge of the upper surface of the second semiconductor layer 23 of the semiconductor structure 20, and the distance (D5) may be greater than 1 μm and less than 10 μm. The distance (D5) can be determined according to actual needs. For example, the distance (D5) may range from 1.5 μm to 4 μm, or from 4 μm to 7 μm. A smaller distance (D5) may reduce the driving voltage of the light-emitting device. A larger distance (D5) may prevent an electrostatic breakdown at an edge of the light-emitting device.

Referring to FIGS. 13 to 15, a third embodiment of the light-emitting device according to the disclosure is generally similar to the second embodiment, except that, in the third embodiment, the light-emitting device further includes a current block layer 60.

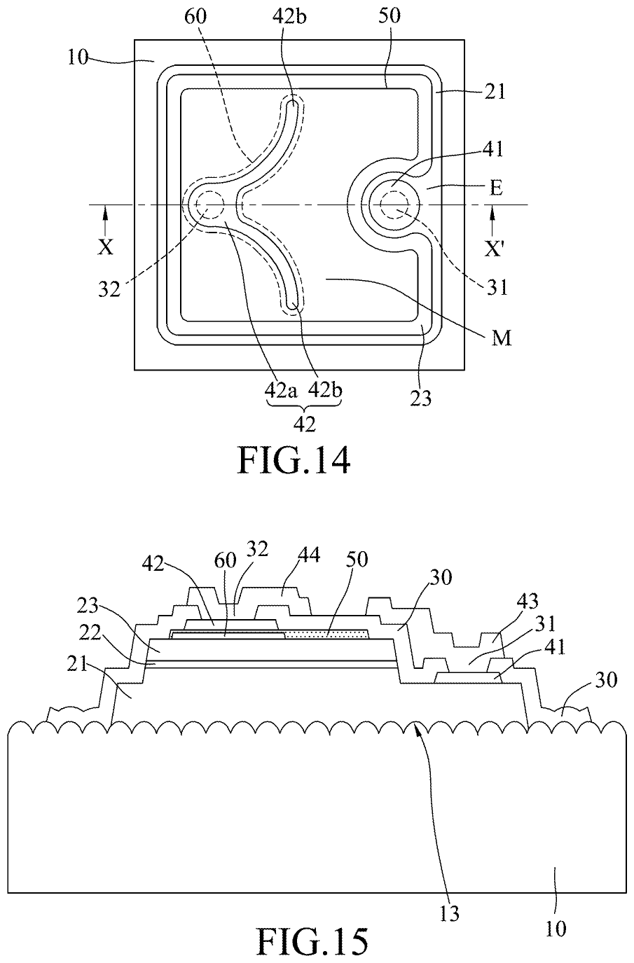

The current block layer 60 may be interposed between the transparent conductive layer 50 and the second semiconductor layer 23 of the semiconductor structure 20. As shown in FIGS. 14 and 15, the current block layer 60 is aligned under the second contact electrode 42 (e.g., under the main part 42a and each of the extending parts 42b).

The current block layer 60 can block a current flowing from the second contact electrode 42 to the second semiconductor layer 23 vertically through the transparent conductive layer 50, so as to reduce current crowding near the second contact electrode 42, thereby improving the current spread performance. The current blocking layer 60 may be insulating and may include an insulation material such as SiOₓ and SiNₓ. The current blocking layer 60 may be formed as a single layer.

The current blocking layer 60 may have an area larger than that of the second contact electrode 42 disposed thereon to allow the second contact electrode 42 to be positioned within an upper area of the current blocking layer 60. Besides, the current blocking layer 60 may have an inclined lateral surface to prevent a corner part of the transparent conductive layer 50 from peeling off or shorting out. In certain embodiments, the current blocking layer 60 has a similar shape to that of the second contact electrode 42, and has a width larger than that of the second contact electrode 42. In certain embodiments, the current blocking layer 60 has an upper surface having a width at least 1 μm greater than that of an lower surface of the second contact electrode 42, and a projection of the second contact electrode 42 on the upper surface of the current blocking layer 60 falls within the upper surface of the current blocking layer 60. In some embodiments, the edge of the current blocking layer 60 is widened outward from the edge of the second contact electrode 42 by at least 2 μm, so that the width of the current blocking layer 60 is larger than that of the second contact electrode 42 by at least 4 μm. In some embodiments, the edge of the current blocking layer 60 is widened outward from the edge of the second contact electrode 42 by at least 4 μm. Such configuration is advantageous to facilitate current spreading.

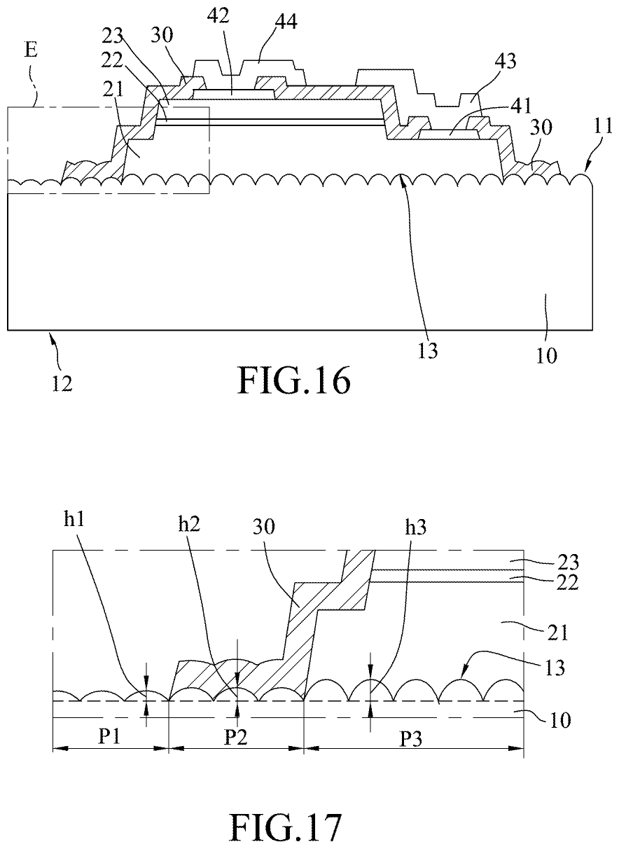

Referring to FIGS. 16 and 17, a fourth embodiment of the light-emitting device according to the disclosure is generally similar to the first embodiment, except that, in the fourth embodiment, the configuration of the uneven structure 13 may be simplified.

In this embodiment, the uneven structures 13 have protrusions that have heights varying by areas of the upper surface 11 of the substrate 10. Specifically, as shown in FIG. 17, the upper surface 11 of the substrate 10 includes three areas: a first area P1 that is exposed from the semiconductor structure 20 and that is not covered by the insulating reflective layer 30; a second area P2 that is exposed from the semiconductor structure 20 and that is covered by the insulating reflective layer 30; and a third area P3 that is covered by the semiconductor structure 20. The uneven structure 13 may be formed across the three areas P1, P2, P3. In such case, the protrusions of the uneven structure 13 located in the third area P3 may have heights higher than that of those located in the second area P2, for facilitating the covering with the insulating reflective layer 30. As well, the protrusions of the uneven structure 13 located in the second area P2 may have heights higher than that of those located in the first area P1, for facilitating the dicing process in the manufacturing of the light-emitting device.

The advantages of the light-emitting device according to the disclosure are described below with comparing AOI results of a sample according to the disclosure and the comparative example.

Referring to FIG. 13, the insulating reflective layer 30 is four-sided and has upper, lower, left and right lateral sides. The inclined lateral surface at the upper lateral side of the insulating reflective layer 30 is referred to as the comparative example shown in FIG. 6, where the included angle of the inclined lateral surface is relatively small (e.g., 45°). The inclined lateral surface of the insulating reflective layer 30 at the left, right and lower lateral sides in FIG. 13 is referred to as the sample of the disclosure shown in FIG. 7 where the included angle is not less than 60° (e.g., 75°). Due to the relatively small included angle of the inclined lateral surface of the insulating reflective layer 30 in the comparative example, during an AOI process, axial and ring light rays could not be effectively reflected to an optical signal detection site thus causing failure of judgement.

When the light-emitting device of FIG. 13 was subsequently rotated 90°, 180°, and 270° in clockwise direction to undergo inspection, inspection failure always occurred at the side where the included angle is relatively small.

These results indicate that if the included angle of the inclined lateral surface of the insulating reflective layer 30 is relatively small, regardless of whatever angular positions of the light-emitting device, efficient inspection and detection is impossible at the side of the light-emitting device where the included angle of the inclined lateral surface of the insulating reflective layer 30 is relatively small. On the other hand, the regions of light-emitting device, where a relatively large included angle of the inclined lateral surface of the insulating reflective layer 30 are present, AOI can be performed correctly at any one of angular positions of the light-emitting device.

The light-emitting device according to the disclosure can be used in a lighting device or a display device. Examples of the lighting device includes, but not limited to, COB (Chip on board) lightings, ultraviolet lamps, bulb lamps, and flexible filament lamps. Examples of the display device includes, but not limited to, backlight-equipped display devices and RGB display devices.

The light-emitting device according to the disclosure may be a flip-chip LED. The first and second electrode pads 43, 44 may be connected to a circuit board for an actual application by a reflow soldering or any high temperature process to be fabricated into a display device such as a backlight-equipped display device and an RGB display device.

The disclosure also provides a display device that include a mounting element and the light-emitting device of any one of the embodiments of the disclosure that is mounted on the mounting element. The display device may be a backlight-equipped display device or an RGB display device, and may be used in a television, a cellular phone, a display panel, a computer, or an outdoor display. The mounting element may be a frame for a chip-on-board (COB) LED, a chip-on-glass (COG) LED, or a surface-mounted device (SMD) LED.

It should be noted that, unless otherwise specified, the area of each layer or structure referred to in the disclosure is the projected area projected from above the light-emitting device perpendicular to a horizontal plane; the distance between the layers or structures referred to in the disclosure may be the distance between the projections of the layers or structures on the horizontal plane. When projecting, the light-emitting device should be placed on the horizontal plane in the order of the substrate 10 and the semiconductor structure 20 from lower to upper in a vertical direction that is perpendicular to the horizontal plane.

To sum up, since the light-emitting device according to the disclosure includes the insulating reflective layer 30 having the inclined lateral surface, and the included angle defined between the inclined lateral surface and the upper surface 11 of the substrate 10 is not less than 60°, reflection area of the inclined lateral surface can be reduced significantly, so that the amount of the scattered light will be relatively large, thereby improving the reliability of the light-emitting device, and allowing the light-emitting device to be more easily detected in AOI. In addition, by forming the uneven structure 13 on at least a portion of the upper surface 11 of the substrate 10, the external light extraction efficiency and the crystallinity of the semiconductor structure 20 can be improved.

It should be noted that, although there are many drawbacks in the prior art, each embodiment of the disclosure may alleviate at least one of the drawbacks of the prior art, and is not have to alleviate all of the drawbacks of the prior art. It also should be noted that any details not described in the claims should not be taken as a limitation thereon.

The terms used in the disclosure such as “substrate”, “upper surface”, “lower surface”, “uneven structure”, “semiconductor structure”, “first semiconductor layer”, “light-emitting layer”, “second semiconductor layer”, “insulating reflective layer”, “first through hole”, “second through hole”, “DBR”, “interface layer”, “stacked structure”, “first contact electrode”, “second contact electrode”, “first electrode pad”, “second electrode pad”, “transparent conductive layer”, “current blocking layer”, “atomic layer deposition layer”, “protrusion” are merely used for the sake of explanation, and may be replaced to any other terms.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a substrate that has an upper surface and a lower surface opposite to said upper surface;
a semiconductor structure that is disposed on said upper surface of said substrate, and that includes a first semiconductor layer, a second semiconductor layer, and a light-emitting layer disposed between said first semiconductor layer and said second semiconductor layer, a projection of said semiconductor structure on said upper surface of said substrate having an outer periphery spaced apart a distance (D2) from an outer periphery of said upper surface of said substrate;
an insulating reflective layer that covers at least a part of said semiconductor structure and that has an extending portion extending outwardly from an outer periphery of said semiconductor structure and covering a part of said upper surface of said substrate;
wherein a peripheral end of said extending portion of said insulating reflective layer has an inclined lateral surface, and an included angle defined between said inclined lateral surface and said upper surface of said substrate is not less than 60°.

2. The light-emitting device as claimed in claim 1, wherein said included angle defined between said inclined lateral surface and said upper surface of said substrate is greater than 70° and less than 90°.

3. The light-emitting device as claimed in claim 1, wherein a distance (D1) between said outer periphery of said projection of said semiconductor structure on said upper surface of said substrate and an outer periphery of a projection of an upper surface of said extending portion of said insulating reflective layer on said upper surface of said substrate ranges from 2 μm to 10 μm.

4. The light-emitting device as claimed in claim 1, wherein a distance (D2) between said outer periphery of said projection of said semiconductor structure on said upper surface of said substrate and said outer periphery of said upper surface of said substrate ranges from 5 μm to 30 μm.

5. The light-emitting device as claimed in claim 1, wherein at least a portion of said upper surface of said substrate is formed with an uneven structure that includes structured elements having at least one of a trapezoid-shape, a circular cone-shape, a triangular cone-shape, a hexagonal cone-shape, a circle-like cone-shape, a triangle-like cone-shape, and a hexagon-like cone-shape.

6. The light-emitting device as claimed in claim 1, wherein at least a portion of said upper surface of said substrate is formed with an uneven structure that has at least one layer having a refractive index lower than that of said substrate.

7. The light-emitting device as claimed in claim 1, wherein said insulating reflective layer has a thickness ranging from 1 μm to 10 μm.

8. The light-emitting device as claimed in claim 1, further comprising a transparent conductive layer that is disposed between said semiconductor structure and said insulating reflective layer, a projection of said transparent conductive layer on an upper surface of said second semiconductor layer of said semiconductor structure having an outer periphery spaced apart a distance (D5) from an edge of said upper surface of said second semiconductor layer of said semiconductor structure, said distance (D5) being greater than 1 μm and less than 10 μm.

9. The light-emitting device as claimed in claim 8, further comprising:
a first contact electrode that is disposed on said first semiconductor layer of said semiconductor structure; and
a second contact electrode that is disposed on and electrically connected to said transparent conductive layer, and that includes a main part and an extending part extending from said main part.

10. The light-emitting device as claimed in claim 9, further comprising a current block layer that is interposed between said transparent conductive layer and said semiconductor structure, that is aligned under said second contact electrode, and that has an upper surface having a width at least 1 μm greater than that of a lower surface of said second contact electrode.

11. The light-emitting device as claimed in claim 9, wherein said main part of said second contact electrode has an upper surface having a width ranging from 15 μm to 50 μm.

12. The light-emitting device as claimed in claim 9, wherein said insulating reflective layer further has a first through hole exposing said first contact electrode and a second through hole exposing said second contact electrode, and said light-emitting device further includes:
a first electrode pad that is disposed on said insulating reflective layer and that extends into said first through hole to be electrically connected to said first contact electrode; and
a second electrode pad that is disposed on said insulating reflective layer and that extends into said second through hole to be electrically connected to said second contact electrode.

13. The light-emitting device as claimed in claim 12, wherein a distance (D4) between said first and second electrode pads ranges from 50 μm to 100 μm.

14. The light-emitting device as claimed in claim 12, wherein said second through hole of said insulating reflective layer has a bottom opening, a projection of said bottom opening of said second through hole on an upper surface of said main part of said second contact electrode falling within said upper surface of said main part of said second contact electrode, said upper surface of said main part of said second contact electrode having a width (K6) at least 5 μm greater than a width (K4) of said bottom opening of said second through hole.

15. The light-emitting device as claimed in claim 12, wherein said first through hole of said insulating reflective layer has a bottom opening, a projection of said bottom opening of said first through hole on an upper surface of said first contact electrode falling within said upper surface of said first contact electrode, said upper surface of said first contact electrode having a width (K5) at least 5 μm greater than a width (K3) of said bottom opening of said first through hole.

16. The light-emitting device as claimed in claim 12, wherein said first through hole of said insulating reflective layer has a top opening having a width (K1) greater than 10 μm.

17. The light-emitting device as claimed in claim 12, wherein said second through hole of said insulating reflective layer has a top opening having a width (K2) greater than 10 μm.

18. The light-emitting device as claimed in claim 12, a distance between an outer periphery of a projection of an upper surface of said first electrode pad on said upper surface of said substrate and an outer periphery of a projection of an upper surface of said first contact electrode on said upper surface of said substrate is greater than 2 μm.

19. The light-emitting device as claimed in claim 12, wherein a distance between an outer periphery of a projection of an upper surface of said second electrode pad on said upper surface of said substrate and an outer periphery of a projection of an upper surface of said main part of said second contact electrode on said upper surface of said substrate is greater than 2 μm.

20. A display device, comprising a mounting element and the light-emitting device as claimed in claim 1 that is mounted on said mounting element.
